(19) United States
(12) Patent Application Publication
(10) Pub. No.: US 2006/0128134 A1
(43) Pub. Date: Jun. 15, 2006

(54) Method for re-routing lithography-free microelectronic devices

(75) Inventors: Francois Baleras, Seyssinet (FR); Fanny Delaguillaumie, St Marcellin (FR); Marc Zussy, St Egreve (FR)

Correspondence Address: OBLON, SPIVAK, MCCLELLAND, MAIER & NEUSTADT, P.C., 1940 DUKE STREET, ALEXANDRIA, VA, 22314, US

(73) Assignee: COMMISSARIAT A L'ENERGIE ATOMIQUE, Paris (FR)

(21) Appl. No.: 10/538,889

(22) PCT Filed: Dec. 17, 2003
(86) PCT No.: PCT/FR03/50188

§ 371 Date: Jun. 14, 2005

(51) Int. Cl. H01L 21/44

(52) U.S. Cl. 438/612

(57) ABSTRACT

A method for producing a chip-scale electronic package produced at a substrate level, the substrate including at least one chip having input/output pads on a substrate face. The method a) forms, using a complex mold or stencil, an insulating stress relaxation layer on the front face, the relaxation layer covering the front face of the substrate with a surface relief that provides access wells at input/output pads and protruding parts configured to relax stresses, with each protruding part having a tiered shape including at least one protuberant zone and at least one zone that is recessed in relation to the protuberant zone and is configured to support an electrical bonding pad, b) forms electrically conductive tracks on the relaxation layer to connect input/output pads to the corresponding electrical bonding pads, and c) forms electrical contacts with an exterior on electrical bonding pads.

### TECHNICAL FIELD

The present invention is related to a method for the manufacture of an electronic chip package produced at the substrate level (Wafer Level Chip Scale Package or WLCSP). In the following description, the aforementioned package described in the invention will be referred to as a chip-scale package.

The invention is also concerned with complex moulds or stencils used to produce the aforementioned chip-scale package in accordance with the method in the invention and is also concerned with the aforementioned chip-scale package itself.

The miniaturisation of packages has become an essential requirement for meeting market demands, in particular where the development of portable systems or telecommunications is concerned, but also to allow the number of integrated circuits inputs/outputs to be increased and to reduce the cost of packaging.

In order to meet these demands, the dimensions of electronic packages are getting close to those of integrated circuits (with chip-scale package (or CSP) technology or flip-chip technology, packages with dimensions 1 or 1.2 times the dimensions of the circuits are obtainable). The weight of chip-scale packages and size of connections must also be reduced as much as possible in order to increase the number of inputs/outputs in integrated circuits.

In addition, one approach to reducing the cost of packaging steps is to produce the chip-scale package at the substrate level. The reduction in size of the chip-scale package then poses serious reliability problems: two major problems are well known to those working in the field.

Firstly, humidity or the effect of contamination cause defects in the integrated circuits, with these defects being amplified by the reduction in the package size. It is necessary, therefore, to improve the protection for integrated circuits inside packages.

The second defect is induced by the large differences in thermal expansion between the package and the receiving substrate (printed circuit). For example, for a package which has a coefficient of thermal expansion of 2.6 ppm/° C. and with the epoxy glass making up the printed circuit having a coefficient of 16 ppm/° C., the very large differences in thermal expansion will, especially for ball grid array packages, produce significant stresses in the balls with variations in temperature. These stresses may be sufficiently large to rupture the balls used for the connections. Miniaturisation of packages, therefore, also requires improvements to be made in the reliability of the packaging.

### BACKGROUND OF THE INVENTION

Several methods for manufacturing of chip-scale packages produced at the substrate level, or WLCSPs, already exist.

The widely used method involves rerouting of the integrated circuit inputs/outputs (see FIG. 1 and the document [1] referred to at the end of this description).

FIG. 1 shows a longitudinal section view of a chip-scale package 1 produced using the technique explained in document [1]. Firstly a substrate 2, made up of integrated circuits whose input/output pads are labelled 3 is covered with an insulating layer or passivation layer 4. In order to deposit this layer, spin coating is usually used for polymers, or vapour phase chemical deposition for minerals. The above insulating layer is then opened, either by exposure of the polymer through a masque, or by lithography and etching (that is, by the deposit of a photosensitive resin, then exposure through a masque). The rerouting process itself then commences: first a continuous layer is vaporised onto the integrated circuit, then electrolysis of copper is carried out across a photosensitive resin; this resin is then stripped away and etching of the continuous background takes place. The rerouting lines 5 are obtained in this way. Then a new insulating layer 6 is deposited, which provides demarcation for soldering and finally metallization of the integrated circuit takes place either by spraying or by UBM (“under bump metallization”) chemical deposition; UBM is a metallurgical process for attaching fusible balls 7. Finally, rerouting lines 5 (conductive) are obtained which join input/output pads to the fusible balls 7.

The drawback to this procedure is that it involves at least three lithographic steps. Thus, although the process is carried out at the substrate scale, the number of steps involved in packaging the integrated circuit means that high costs are involved.

The second problem related to this method of manufacture is that if the CSP packages (chip-scale packages) are mounted on printed circuits without resin being interposed (called “underfill” in the technique concerned), the connections produced will then be very weak. Differences in thermal expansion between the CSP and the printed circuit then result in stresses in the peripheral balls, especially if the integrated circuits are wide. For this type of package, therefore, it is essential to add a resin “underfill” beneath the package in order to distribute the stresses over the balls and the “underfill” resin. The problem, however, is that the use of this resin is not necessarily needed for all applications and this generally adds at least one additional step. In addition, the use of this resin makes the repair of components more difficult, since it requires that a defective package be replaced by a new one.

The second innovative method for the manufacture of WLCSP packages has been described by A. Kazama (see document [2] referred to at the end of this description).

A chip-scale package produced using the technique of document [2] is shown in FIG. 2 in a longitudinal cross-section view. As previously, there is a WLCSP package 11 made up of a substrate 12, integrated circuit pads 13 and a passivation layer 14. The difference in relation to the previous document is due to the presence of thick slabs of polymer 18 between the front face of the substrate 12 and the fusible balls 17. These thick polymer slabs allow the stresses between the chip-scale package and the printed circuit to relax.

Rerouting of the input-output pads 13 is achieved through spraying a metallic under-layer followed by Cu/Ni electrolysis across a photosensitive resin. After removing the resin and the under-layer, the rerouting lines 15 are obtained; the “spin coating” method is then used to deposit a photosensitive insulating layer 16. This layer is then exposed through a mask in order to delimit the fusible ball solder pads 17. Finally, after the transfer of the fusible balls, integrated circuits are divided to obtain chip-scale packages.

On completion there is a substrate covered with slabs of polymer 18 whose input/output pads 13 are joined to fusible balls 17 through rerouting lines 15.

This manufacturing method for WLCSP packages allows manufacturing costs to be reduced (the polymer slabs are deposited using screen printing, a low cost process) and reduces mechanical stresses acting on the fusible balls. The method used to deposit the polymer, however, does not allow the integrated circuit input/output pads to be insulated.

Furthermore, the method requires at least two lithographic steps: a step to delimit the metallic tracks and a step to open up the passivation that has been deposited on the metallic tracks.

In addition the lithographic steps are performed on relief surface; the deposition of photosensitive resin on relief surface can prove to be a difficult and delicate operation.

### PRESENTATION OF THE INVENTION

The invention proposes a low cost manufacturing method for WLCSP packages which involves packaging of the integrated circuit at substrate scale and which does not exhibit the problems seen in the prior art.

The method that is the subject of the invention involves using a mould or stencil to create a layer which relaxes stresses between the chip-scale package and the printed circuit to which the said chip-scale package is connected, giving it a tiered shape which subsequently allows rerouting of inputs/outputs to be achieved with fewer lithographic steps than in prior art, or even none at all.

In other terms, the method for producing a chip-scale electronic package at the substrate level, with the aforementioned substrate being made up of at least one chip with this chip having input/output pads on a substrate face known as the front face, includes the following steps:

a) formation, using a complex mould or stencil, of an insulating stress relaxation layer on the aforementioned front face, with the aforementioned relaxation layer covering the front face of the substrate with a surface relief which provides access wells at input/output pads and as well as protruding parts intended to relax stresses, with each protruding part having a tiered shape made up of at least one protuberant zone and at least one zone that is recessed in relation to the aforementioned protuberant zone and is intended to support an electrical bonding pad,

b) formation of electrically conductive tracks on the relaxation layer to connect input/output pads to the corresponding electrical bonding pads,

c) formation of means of electrical contact with the exterior on electrical bonding pads.

Here the use of a polymer layer instead of several polymer slabs as in the prior art allows the input/output pads to be insulated from the rest of the integrated circuits.

In general terms, integrated circuits located on the substrate will include input/output pads in aluminium, copper or other materials and a passivation layer in mineral or organic materials or both. These circuits may also include various finishes, for example, a Ni/Au chemical deposit.

In one particular form of the invention, the aforementioned procedure further includes, between the above steps b) and c), a step for the formation of an encapsulation layer on the relaxation layer, with exposure of the electrical bonding pads.

The stress relaxation layer may be created using various methods.

In one embodiment, the aforementioned layer may be created using a mould. In this case, the steps are as follows:

1) fill the mould with a given relaxation polymer or apply the said polymer directly onto the front face of the substrate,

2) align the mould on the front face of the substrate,

3) press the mould onto the front face of the substrate,

4) cure the polymer,

5) remove the mould.

If it is decided to apply the relaxation polymer directly onto the substrate, there is a choice of different methods available, including spreading or dispensing.

In another embodiment, the aforementioned layer may this time be created using a stencil. In this case, the steps are as follows:

1) apply the stencil to the front face of the substrate,

2) fill the orifices in the stencil with a given relaxation polymer,

3) cure the polymer and separate the stencil from the substrate.

The two actions in this last step are interchangeable: the polymer may be cured and the stencil then separated from the substrate, but the separation of the stencil may in certain cases also be carried out before curing the polymer.

Advantageously, the aforementioned given relaxation polymer used in the above production methods is selected from amongst polyimide, BCB or any other polymer that is capable of stress relaxation.

After a stress relaxation layer is obtained on the front face of the substrate, there may be polymer residues on the input/output pads which might possibly prevent contact being made on these pads. It is advantageous if these polymer residues are removed; a cleaning process may be used for this such as plasma treatment or any other similar technique.

The rerouting step or step for formation of electrically conductive tracks to connect integrated circuits input/output pads to the corresponding electrical bonding pads is simplified as a result of the complex topology of the previously created relaxation layer.

The complex topology of the relaxation layer means that this rerouting step for the integrated circuit inputs/outputs may not require a lithographic step. In this case, two options are available:

if it is wished to produce a deposit of conductive material over the entire front face of the substrate, the following steps are followed:

a) deposit of a conductive material on the front face of the substrate covered with the relaxation layer,

b) separation of the rerouting lines and formation of the electrical bonding pads by removal of conductive material located in the protuberant zone(s) of the protruding parts of the relaxation layer by mechanical lapping or by mechanical/chemical polishing.

As for the two techniques for separation of rerouting lines, they allow metal to be removed from the surface without attacking the metal situated in zones that are lower in relation to the level up to which the removal is carried out.

if conductor metal only needs to be deposited in input-output pad access wells and in the zones that are recessed in relation to the protuberant zone(s) of parts protruding from the relaxation layer, chemical deposition of conductive material is performed only at these locations. The step in which conductive material is removed at the surface of the relaxation layer, that is, at the protuberant zone(s) of the protruding parts, in order to separate rerouting lines will not then be necessary.

It is advantageous if the conductive material is a metal.

Traditional rerouting techniques can also be used which, due to the complex topology of the relaxation layer, require only a single lithography step. In this case, the following steps can be followed:

a) deposit of a conductive material on the front face of the substrate covered with the relaxation layer,

b) lithography,

c) chemical etching,

d) stripping,

or even the following steps:

a) lithographic metallization of the front face of the substrate,

b) electrolysis,

c) stripping,

d) chemical etching,

Advantageously, the deposition of conductive material mentioned earlier involves metallization. In order to carry out this metallization, spraying, evaporation, electro-deposition or chemical deposition of one or more metals is carried out.

Once the reroutings have been created, encapsulation of packages can be carried out in order to extend their working life. Various methods for encapsulation exist: screen printing, dispensing moulding, spreading etc.

In the same way, encapsulation may be total or partial.

In one embodiment, the encapsulation formation step involves the following steps:

a) deposition of a layer of polymer over the entire front face of the substrate covered with the relaxation layer,

b) levelling of the front face of the substrate,

c) freeing the electrical bonding pads.

In another method of manufacture, the encapsulation formation step involves the following steps:

a) levelling of the front face of the substrate covered with the relaxation layer,

b) filling the access wells and the recessed zones in the front face of the substrate with a thick polymer layer,

c) freeing the electrical bonding pads.

The freeing up of electrical bonding pads is achieved by lapping, mechanical/chemical polishing, etching or by any other technique.

After the step in which the front face of the substrate is levelled, cuts could be made in the front face of the substrate, taking care not to cut completely through the relaxation layer. Then an encapsulant is deposited on the rear face of the substrate and in the cuts in the front face of the substrate. In these conditions, the edges of integrated circuits will also be protected close to the chip-scale package cuts.

Then, means of electrical contact with the exterior must be introduced onto the electrical bonding pads located on the relaxation layer. This step may be carried out before or after the levelling of the substrate, but it is preferably carried out after levelling. Actually, levelling allows demarcation of electrical bonding pads to be carried out.

Advantageously, the means of making electrical contact with the exterior on electrical bonding pads are fusible balls.

In this case fusible balls will be installed on the electrical bonding pads by a technique selected from electrolysis of a fusible alloy, screen-printing of solder paste, transfer of balls or any other technique.

In one type of manufacture, these means of electrical contact are chosen from anisotropic conductive films and adhesives.

Finally, the step for separation of chip-scale packages must be carried out. This separation or marking out is performed by making cuts using a saw, laser etching or any other similar means.

This method for manufacturing WLCSP packages may be supplemented by additional steps.

First of all, it may be necessary to reduce the thickness of packages. To do this, before or after introduction of the means of electrical contact with the exterior on the electrical bonding pads, the rear face of the substrate is made thinner by lapping, mechanical/electrical polishing or any other technique.

For example, in the case of silicon, the substrate thickness can be reduced to 50 μm. Reduction of the thickness until it reaches the active thickness of the silicon may even be envisaged.

The method may also be supplemented by the following steps:

a) the creation of slots in the rear face of the substrate (by laser or chemical etching, by cutting or any other technique) until the metallic layers represented by the integrated circuit input-output pads or by the electrically conductive tracks are reached,

b) deposition, possibly localised, of a metallic layer (55) on the rear face of the substrate,

c) removal of the metallization located on the surface of the rear face of the substrate.

The invention is also concerned with complex moulds or stencils designed to create a chip-scale package as described in the method in the invention.

It is an advantage if these complex moulds or stencils are made using at least one technique from amongst wet or dry etching, electroforming, adhesion of several pierced or un-pierced polymer films, moulding, laser etching or any other technique which allows a complex topography to be created.

Advantageously, the aforementioned moulds or stencils are made from silicon, metal, polymer or any similar material. It should be noted that releasing small parts from moulds is facilitated by the use of polymer moulds or stencils.

The invention is also concerned with chip-scale packages manufactured at the substrate level characterised by the fact that they are produced using the method as described in the invention.

The method as described in the invention offers a number of advantages, notably a reduction in the number of steps in the manufacture of chip-scale packages. Actually, the moulding or stencil technique allows to create at the same time the topology required to create rerouting of input/outputs and the thermo-mechanical stress relaxation layer. The aforementioned moulds or stencils also allow the number of photolithographic steps to be reduced. Consequently, they reduce the total number of steps required for the manufacture of the chip-scale package and in this way reduce the manufacturing cost of the aforementioned package. In addition, once these moulds or stencils are made, they may be re-used, which also reduces the cost of package manufacture.

### BRIEF DESCRIPTION OF THE DRAWINGS

Other characteristics and advantages of the invention will be more apparent in the light of the following description. This description deals with examples of manufacture, given for explanation and in a non-restrictive manner, by making reference to the appended drawings, which include:

FIGS. 1 and 2 illustrate the existing practices presented earlier in this description,

FIGS. 3a and 3b illustrate the topology of the complex mould (FIG. 3a) and of the complex stencil (FIG. 3b) as described in the invention,

FIGS. 4a to 4g illustrate one method of manufacture of WLCSP packages as described in the invention,

FIGS. 5a to 5c illustrate a supplement to manufacture in order to obtain complete encapsulation of the integrated circuit,

FIGS. 6a to 6g illustrate another method of manufacture of WLCSP packages in accordance with the invention,

FIG. 7 illustrates encapsulation of all surfaces of the integrated circuit created at substrate level.

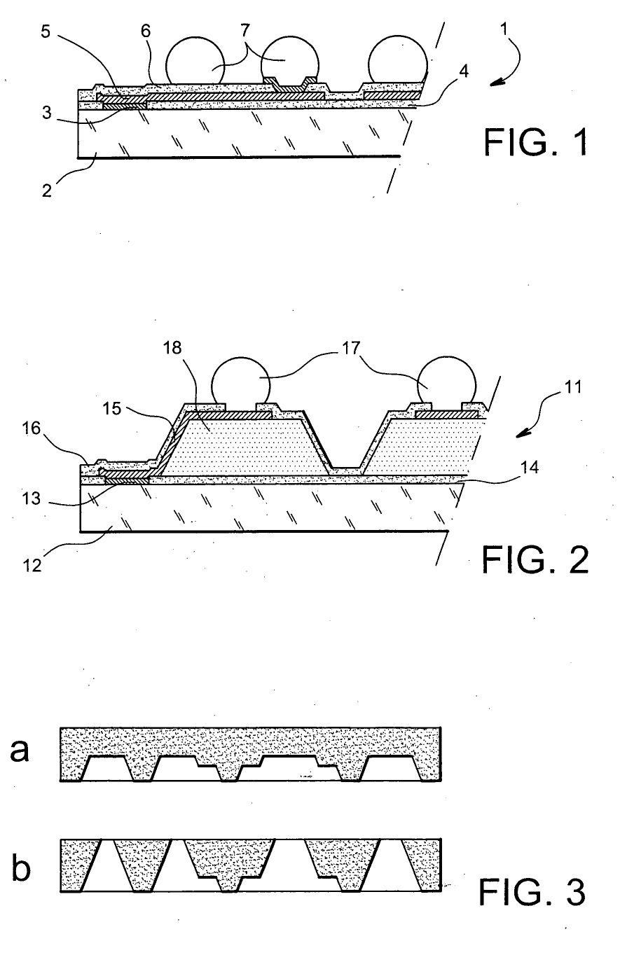

It should be noted that the figures are not drawn at the substrate scale.

### DETAILED DESCRIPTION OF PREFERRED EMBODIMENTS

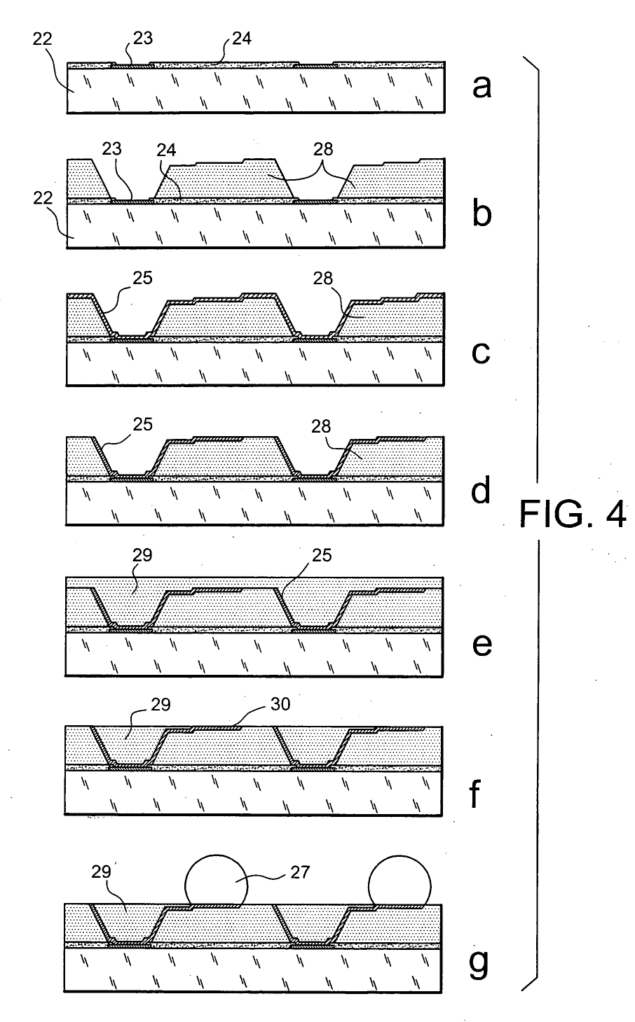

A method for manufacturing a WLCSP package in accordance with the present invention is shown in FIGS. 4a to 4g.

As FIG. 4a shows, a substrate 22 made up of integrated circuit with each circuit having input/output pads 23 and a passivation layer 24 is provided, with the aforementioned elements being obtained by methods described in the prior art.

During step b, the said stress relaxation layer labelled 28 is made on the said substrate (FIG. 4b). This step is carried out either by moulding of the polymer onto the substrate using a complex mould, or by screen printing of the polymer through a complex stencil onto the substrate or by transfer of the polymer (by creating the polymer structure on another support using a complex mould or stencil, and then adhering it onto the substrate).

This step may be accompanied by a cleaning process (for example plasma treatment) to remove polymer residues from integrated circuit input/output pads 23.

Then a metallic layer labelled 25 is deposited over the entire surface of the substrate (by spraying on a layer of titanium/copper, for example) (FIG. 4c). If it is wished to increase the thickness of the metallic layer, this step may be supplemented by an electro-deposition of copper. This metallization step may also be carried out by chemical deposition of Ni/Au over the entire surface or by selective deposition (localised metallization in access wells and in recessed zones).

Then metallic tracks are isolated by the removal of surface metallization (FIG. 4d). This step is performed by mechanical-chemical polishing, etching or any other technique. It should be noted that in the case of localised chemical deposition, this step is not necessary.

Under these conditions, metallization is retained in the pad access pits and in all zones that are recessed relative to the upper machined surface of the relaxation layer.

Then, the front face of the substrate is levelled by the deposition of an insulating layer, labelled 29, for example by dispensation of “underfill” resin that is levelled by spin coating, by moulding of a polymer or by any other technique (FIG. 4e).

This insulating layer is then opened up by plasma etching, polishing or by any other technique to release the ball attachment pads (FIG. 4f).

Finally, ball coating of the substrate is performed (FIG. 4g). Any techniques for producing fusible balls labelled 27 may be used

A full encapsulation of the integrated circuits may be required. In this case, the encapsulation steps must be integrated between steps f and g above.

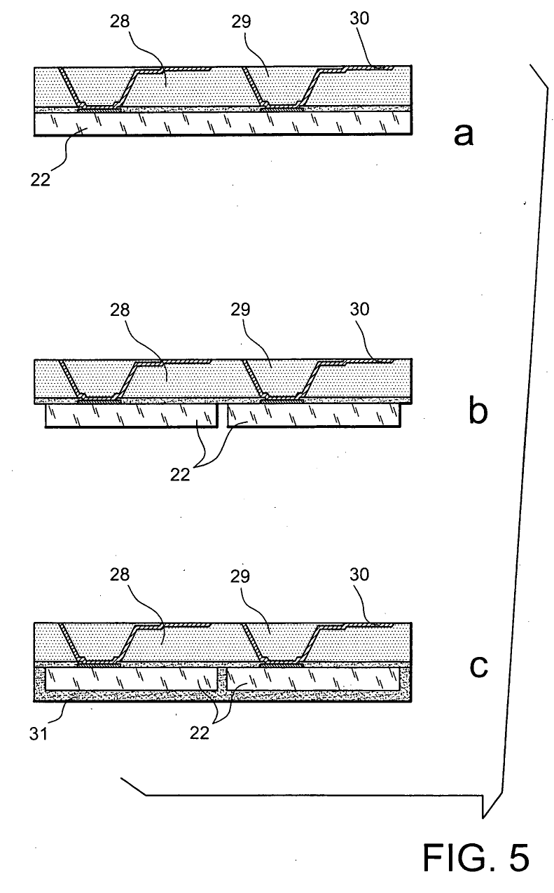

First of all, thinning of the rear face of the substrate 22 may be performed by lapping or any other technique, but this step is not mandatory (FIG. 5a).

The rear face of substrate 22 is then cut away until the passivation layer 24 of the integrated circuits is reached (FIG. 5b). This operation may be performed by mechanical cutting, by laser or by any other technique.

The last step involves full encapsulation of the rear face of the substrate 22 and filling in the slots made earlier (FIG. 5c). This step may be carried out by moulding, by dispensing or by any other technique for depositing insulation (labelled 31).

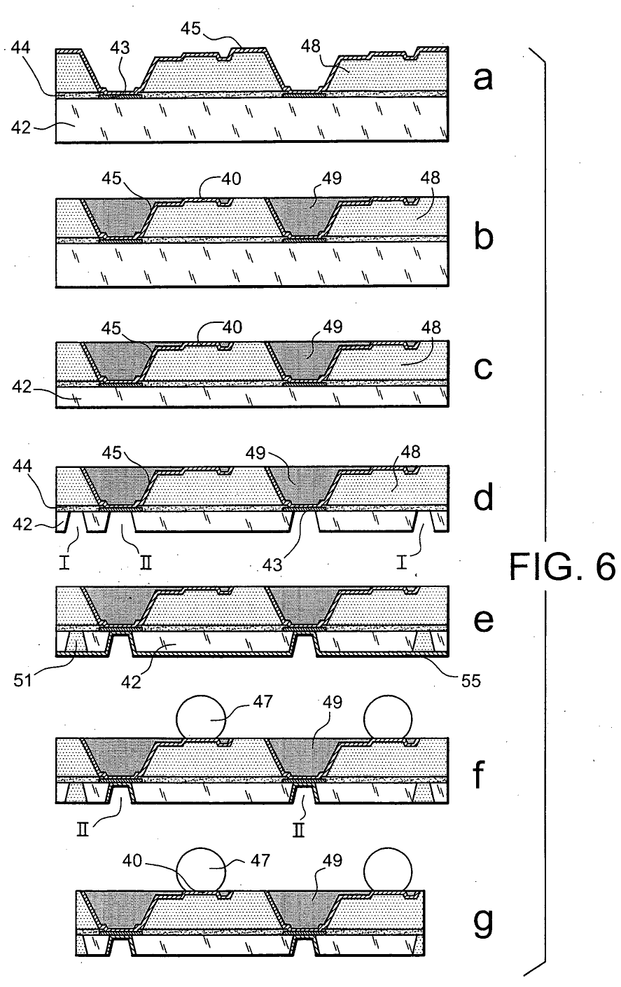

FIGS. 6a to 6g illustrate another method of manufacture of WLCSP packages. This mode of manufacture involves establishing front face/rear face contact and full encapsulation of the integrated circuits.

The steps for formation of the relaxation layer on the integrated circuits and re-routing are identical to the previously described procedure (see FIGS. 4a to 4c): the device shown in FIG. 6a is obtained. Here the demarcation of attachment pads 40 for balls 47 takes a different form: each attachment pad 40 is surrounded by a slot in order to improve the demarcation of the solder zone. The same steps as those shown in FIGS. 4d to 4f are carried out and the device in FIG. 6b is obtained: the recessed zones and the access wells above the input-output pads have been filled in by deposition of an insulating layer 49.

Then, in order to make the establishment of front face/rear face contact possible, the thickness of the substrate 42 (FIG. 6c) starts to be reduced. This is not a mandatory step, but it facilitates establishment of contact with the front face of the substrate and later separation of the chip-scale packages.

Then, as in FIG. 6d, slots are made in the rear face of the substrate to demarcate the integrated circuits (cuts I are made until the passivation layer 44 is reached) and to establish contact between the input/output pads (cuts II are made until the pads 43 are reached). This step may be performed by cutting or by etching. If the etching option is taken, wells are made at the input/output pads 43.

Then the rear face of the substrate must be insulated by depositing an insulating layer 51 in the cuts; this step may be performed by moulding or screen-printing. To be certain that the contacts are insulated, the slots at the said pads are partly filled (not shown in the figure). In order to establish contact on the input/output pads, the metallization step may be preceded by an etching step (for example by laser, by plasma etc.) of the insulating layer at the contacts.

Metallization of the rear face of the substrate is then carried out using the same method as described previously (FIG. 6e): a metallic layer 55 is obtained which covers the entire rear face of the substrate 42.

Then the metallization 55 is isolated by mechanical-chemical polishing or by lapping (or by any other technique) of the surface of the rear face of the substrate. This step may be carried out after an encapsulation step (step not illustrated).

Finally, ball coating of the substrate is performed by placing fusible balls 47 on the attachment pads 40 (FIG. 6f) and separation of the chip-scale packages is performed (FIG. 6g) by cutting at cuts I.

Other variants of chip-scale packages can be obtained.

For example, in once particular mode of production, several of these chip-scale packages offering front face/rear face rerouting can be assembled and the interstices can be filled in using “underfill” resin. The assembly could also be made after cutting of the chip-scale packages. In this way a three dimensional module is obtained.

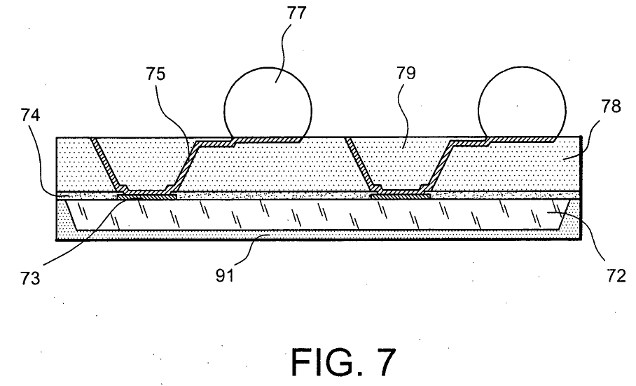

Total encapsulation of the chip-scale package can also be carried out, that is, encapsulation of the front face and of the rear face of the substrate, possibly after reducing the substrate thickness (FIG. 7). In this example, the substrate 72 includes integrated circuits composed of input/output pads 73 and a passivation layer 74; the integrated circuits are then covered with a stress relaxation layer 78 which provides access wells which leave the input/output pads 73 accessible, with the said input/output pads and fusible balls 77 which overhang the relaxation layer 78 being linked by re-routing lines 75. An insulating layer 79 fills the access wells and recessed zones on the front face of the substrate, and an insulating layer 91 covers the rear face of the substrate.

It should be noted that the versions illustrated in FIGS. 6g and 7 are non-restrictive, it being possible in particular to combine the two versions.

### BIBLIOGRAPHY

[1] Dr Philip GARROU, Packaging and Manufacturing Technologies Society, ref IEEE Components, October 2000.
[2] Atsushi KAZAMA, Development of Low-Cost and Highly Reliable Wafer Process Package, ref IEEE, Electronic Components and Technology Conference, 2001.

1-24. (canceled)

25. A method for producing a chip-scale electronic package carried out at a substrate level, with a substrate including at least one chip having input/output pads on a substrate face as a front face, the method comprising:
a) forming, using a complex mould or stencil, an insulating stress relaxation layer on the front face, the relaxation layer covering the front face of the substrate with a relief surface that provides access wells to input/output pads and protruding parts configured to relax stresses, each protruding part having a tiered shape including at least one protuberant zone and at least one zone that is recessed relative to the protuberant zone, the recessed zone configured to support an electrical bonding pad;
b) forming electrically conductive tracks on the relaxation layer to connect input/output pads to the corresponding electrical bonding pads; and
c) forming electrical contacts with an exterior on the electrical bonding pads.

26. A method according to claim 25, further comprising, between b) and c), forming an encapsulation layer on the relaxation layer with exposure of the electrical bonding pads.

27. A method according to claim 25, in which, forming the stress relaxation layer using a mold comprises:
1) filling the mold with a given relaxation polymer or applying the polymer directly onto the front face of the substrate;
2) aligning the mold on the front face of the substrate;
3) pressing the mold on the front face of the substrate;
4) curing the polymer;
5) removing the mold.

28. A method according to claim 25, in which, forming the stress relaxation layer using a stencil comprises:
1) applying the stencil to the front face of the substrate;
2) filling orifices in the stencil with a given relaxation polymer;
3) curing the polymer and separate the stencil from the substrate.

29. A method according to claim 27, in which the given relaxation polymer is selected from amongst polyimide, BCB, or any other polymer capable of relieving stresses.

30. A method according to claim 27, in which, after the stress relaxation layer is obtained on the front face of the substrate, polymer residues found on the input/output pads are removed.

31. A method according to claim 25, in which the forming electrically conductive tracks comprises:
a) depositing a conductive material on the front face of the substrate covered with the relaxation layer;
b) separating rerouting lines and forming the electrical bonding pads by removal of conductive material located at the at least one protuberant zone of the protruding parts of the relaxation layer by mechanical lapping or by mechanical-chemical polishing.

32. A method according to claim 25, in which the forming electrically conductive tracks is performed by chemical deposition of conductive material in access wells for input/output pads and in zones that are recessed in relation to the at least one protuberant zone of the protruding parts of the relaxation layer.

33. A method according to claim 32, in which the conductive material is a metal.

34. A method according to claim 25, in which the forming electrically conductive tracks comprises:
a) depositing a conductive material on the front face of the substrate covered with the relaxation layer;
b) lithography;
c) chemical etching;
d) stripping.

35. A method according to claim 31, in which the depositing conductive material involves metallization.

36. A method according to claim 25, in which the forming electrically conductive tracks comprises:
a) lithographic metallization of the front face of the substrate covered with the relaxation layer,
b) electrolysis;
c) stripping;
d) chemical etching.

37. A method according to claim 26, in which the forming the encapsulation layer comprises:
a) depositing a layer of polymer over the entire front face of the substrate covered with the relaxation layer,
b) levelling the front face of the substrate;
c) exposing the electrical bonding pads.

38. A method according to claim 26, in which the forming the encapsulation layer comprises:
a) levelling the front face of the substrate;
b) filling the access wells and recessed zones in the front face of the substrate with a thick polymer layer;
c) exposing the electrical bonding pads.

39. A method according to claim 25, in which the electrical contacts with the exterior on the electrical bonding pads comprise fusible balls.

40. A method according to claim 39, in which the fusible balls are introduced onto the electrical bonding pads using a technique selected from electrolysis of a fusible alloy, screen-printing of solder paste, and ball transfer.

41. A method according to claim 25, in which the electrical contacts with the exterior on the electrical bonding pads are selected from amongst anisotropic conductive films and adhesives.

42. A method according to claim 25, further comprising d) separating electronic chip-scale packages created at the substrate level.

43. A method according to claim 25, in which, before or after the forming of the electrical contacts with the exterior on the electrical bonding pads, the rear face of the substrate is made thinner by lapping, mechanical-chemical polishing, or any other technique.

44. A method according to claim 25, further comprising:
a) creating slots in the rear face of the substrate until the metallic layers represented by the integrated circuit input-output pads or by electrically conductive tracks are reached;
b) depositing, possibly localized, a metallic layer on the rear face of the substrate;
c) removing the metallization located on the surface of the rear face of the substrate.

45. A complex mold or stencil configured to create a chip-scale package using the method described in claim 25.

46. A complex mold or stencil according to claim 45, which is made using at least one technique from amongst wet or dry etching, electroforming, adhesion of plural pierced or un-pierced polymer films, molding, laser etching.

47. A complex mold or stencil according to claim 45, which is made from silicon, metal, polymer.

48. A chip-scale package manufactured at the substrate level created using the method according to claim 25.
